(19) United States
(12) Patent Application Publication
(10) Pub. No.: US 2007/0200227 A1
(43) Pub. Date: Aug. 30, 2007

(54) Power semiconductor arrangement

(76) Inventors: Thomas Licht, Warstein (DE); Thomas Passe, Epscheid (DE)

Correspondence Address: BAKER BOTTS, L.L.P., 98 SAN JACINTO BLVD., SUITE 1500, AUSTIN, TX, 78701-4039, US

(21) Appl. No.: 11/549,765

(22) Filed: Oct. 16, 2006

Related U.S. Application Data
(63) Continuation of application No. PCT/EP05/03617, filed on Apr. 6, 2005.

(30) Foreign Application Priority Data
Apr. 16, 2004 (DE) DE102004 018475.5

(51) Int. Cl. H01L 23/34

(52) U.S. Cl. 257/718; 257/719

(57) ABSTRACT

A power semiconductor arrangement has a heat-removing base with at least one planar exterior. The base consists of a metal material or is provided with a metal coat. The exterior is at least partially provided with an electrically insulating oxide layer on top of the metal material. The power semiconductor arrangement also has a power semiconductor component that is disposed on the one exterior of the base in such a manner that it is electrically insulated from the base by the oxide layer. An electrically insulated film is at least partially laminated onto the one exterior across the power semiconductor component. The film, in the area of the power semiconductor component, is provided with recesses for contacting the power semiconductor component. An upper metallization layer is applied to the power semiconductor component on top of the film and its recesses across a large area thereof or in a structured manner.

### CROSS-REFERENCE TO RELATED APPLICATIONS

This application is a continuation of co-pending International Application No. PCT/EP2005/003617 filed Apr. 6, 2005, which designates the United States, and claims priority to German application number DE 10 2004 018 475.5 filed Apr. 16, 2004.

### TECHNICAL FIELD

The invention lies in the field of power circuit technology and relates to a power semiconductor arrangement comprising, for example, a heat sink or a heat-dissipating substrate for mounting, making contact with and cooling electrical devices, in particular power semiconductor devices.

### BACKGROUND

DE 199 42 915 A1 discloses a substrate, also referred to as DCB (Direct Copper Bonding), comprising a ceramic carrier material metalized (e.g. coated with copper) on both sides, which carries a plurality of devices (Power Semiconductor Modules) on the one top side, the so-called layout or placement side. The devices are electrically connected to conductor track structures formed in the top-side metalization.

The metalized underside of the substrate is in physical contact with a cooling element in order to be able to dissipate heat loss occurring during operation of the devices. Said heat loss could otherwise lead to damage to devices or components or shorten the service life thereof.

It is necessary in this case to electrically insulate the devices from one another and/or from conductive components (e.g. a cooling element) provided on the underside. Particularly in the case of discrete power components, such as e.g. power transistors in TO 220 packages, there is often no electrical insulation with respect to the heat dissipation contact area of the package. In principle, it is conceivable in these cases to use films or mica laminae for insulation. However, these have to be handled and positioned individually during mounting, resulting in complicated mounting. Moreover, this electrical insulation also leads to an undesired thermal insulation.

Besides good thermal coupling to the cooling element with sufficient electrical insulation, a high mechanical strength of the substrate is also desired. There are mutually conflicting requirements in this respect: on the one hand, a small substrate thickness (carrier material thickness) is desirable for a good thermal conductivity. On the other hand, a high mechanical stability (breaking strength) is desired, which decreases, however, in the case of ceramic substrate materials with reduced layer thickness of the brittle substrate material.

The use of much less brittle and therefore breaking-insensitive plastic as carrier material metalized on both sides for the substrate using so-called IMS technology is conceivable as an alternative. The fields of application are limited owing to the considerably poorer thermal stability of plastics. Moreover, the way in which plastics are applied requires higher layer thicknesses. Since plastic has a much poorer thermal conductance in comparison with ceramics, however, a larger layer thickness leads to a significantly poorer heat dissipation with the problems outlined in the introduction.

Furthermore, there is also the problem of electrically interconnecting the components and also electrically connecting them externally. These connections are usually performed at the side of the component opposite to the heat sink, by means of so-called bonding technology. For this purpose, connecting wires are fixed by means of ultrasound to the components to be connected. Besides the increased susceptibility to faults during production and in operation, what are highly disadvantageous are primarily also the large structural height, current constrictions and the practically impossible cooling of the top side of the components on account of the connecting wires situated there.

### SUMMARY

According to an embodiment, a power semiconductor arrangement may comprise a heat-dissipating basic body having at least one exterior side formed in planar fashion, the basic body comprising metallic material or being provided with a layer made of metallic material and, at its one exterior side, an electrically insulating oxide layer being at least partly formed on the metallic material. Furthermore, at least one power semiconductor device is provided which is arranged on said one exterior side of the basic body in such a way that it is electrically insulated from the basic body by the oxide layer. An electrically insulating film is at least partly laminated onto said one exterior side across said one power semiconductor device, the film having cutouts for making contact with the power semiconductor device in the region of said one power semiconductor device. Finally, an upper metalization is applied to the film and, in the cutouts thereof, also to the power semiconductor device in large-area fashion or in patterned fashion.

### BRIEF DESCRIPTION OF THE DRAWINGS

The invention is explained in more detail below on the basis of the exemplary embodiments illustrated in the figures of the drawing, in which:

FIG. 1 shows a basic schematic diagram of the lower part of a power semiconductor module with a substrate,

FIGS. 2 and 3 show details from a substrate according to an embodiment with oxide layers grown thereon,

FIGS. 4 and 5 show details from a substrate with applied metalizations,

FIGS. 6 and 7 show a substrate optimized with regard to the mechanical stresses with applied oxide islands in plan view and cross section,

FIG. 8 schematically shows a process for oxide layer patterning,

FIGS. 9 and 10 show possible shapings of the basic body,

FIG. 11 shows a basic schematic diagram of a power semiconductor module according to an embodiment, and

FIG. 12 shows a basic schematic diagram of a development of the power semiconductor module according to FIG. 11.

### DETAILED DESCRIPTION

According to different embodiments, a heat dissipating insulation layer that may serve as a substrate or heat sink, for example, is provided, with a basic body that comprises metallic material or is provided with a layer made of metallic material, at least one electrical device being intended to be arranged on the top side thereof, and with an electrically insulating oxide layer that is formed on the basic body over the whole area or partly in the form of oxide layer islands and insulates at least one active or passive device (transistor, IGBT, resistor, busbar, conductor track, etc.), the oxide layer being formed by oxidation of the metallic material.

A first aspect consists in the fact that the electrical insulation of the device is realized by means of an oxide layer that is produced from the basic body material or from a suitable oxidizable coating of the basic body. The oxide layer can be produced directly on the basic body. A thermal conductivity which, in terms of its quality, entirely corresponds to the DCB technology mentioned in the introduction is thus ensured.

A further aspect consists in the fact that very small insulation layer thicknesses can be realized without mechanical stability problems arising. This is because the mechanical strength and stiffness are advantageously ensured independently of the insulation layer thickness by the basic body, which can be dimensioned depending on the mechanical loading to be expected.

A further aspect brings about the reduction of the structural volume, the improvement of the thermal impedance of electrical components and connecting conductors and also the reduction of the static and dynamic electrical losses by the utilization of planar metalization levels at the top side of the components, which are applied in particular by means of metal spraying technology.

In the case of this solution path, the construction inductances and also the connecting resistances can again be reduced and the electrical losses occurring in the module can thus be reduced. A low-resistance and low-inductance construction technology is highly advantageous precisely in the automotive sector, given the high currents. Since the static power losses are involved quadratically with the current, the low-resistance electrical connection is crucial in the case of low-voltage applications.

The structural volume is likewise reduced by the small layer thickness. By means of suitable materials, heat dissipation on both sides can furthermore be realized since the surface is now approximately planar and the distances between the metalization surface and the second heat-dissipating structure (for example heat sink) can thus be kept small, with the result that the component's heat dissipation is improved.

The achievement, therefore, is to produce the electrical connections between the electrical components and to the terminal elements in the next higher system level by means of a suitable metalization layer (for example by means of metal spraying technology or laminating technology) in order to enable an improved heat dissipation, to obtain a lower power loss of the module and also to realize a smaller structural volume. Furthermore, with the utilization of electrical insulation films, the area to be oxidized is decreased and this reduces the process outlay during the oxidation method.

With regard to the different thermal expansion properties of oxide layer and metallic starting material, it may be advantageous, particularly in the case of large-area heat-dissipating insulation layers, if the oxide layer covers only one region or—as it were in insular fashion—a plurality of regions of the heat-dissipating insulation layer or the metallic layer, to be precise at the locations at which devices or assemblies are intended to be mounted in an electrically insulated manner.

The thickness of the insulating oxide layer can advantageously be controlled by the process parameters during the oxidation operation (e.g. in the case of the anodizing method known per se by the choice of voltage, current intensity, temperature and/or oxidation duration) and be optimally adapted to the respective electrical insulation requirements. Further known oxidation methods are plasma electrolytical oxidation (PEO) or Micro Arc Oxidation (MAO). This advantageously opens up the possibility of local optimization of the insulation layer thickness depending on the voltage to be insulated (potential difference). In other words: the oxide layer can be formed with different thicknesses depending on the voltage to be insulated from the device.

In order to further optimize the properties of, in particular, relatively large insulation layer thicknesses, one embodiment provides for further material for increasing the electrical insulation properties and/or the mechanical strength and/or the thermal conductivity additionally to be applied to and/or introduced into the oxide layer. Materials of this type are also known by the term “filler”.

Thus, by way of example, epoxy material may be provided as an additional insulation layer. For increasing the thermal conductivity, material having a good thermal conductivity—e.g. ceramic material or carbon—may be introduced into the epoxy material.

An embodiment provides for a top-side metalization for mounting and making contact with the device to be provided on the oxide layer.

Said metalization may be produced by various methods. It may be applied e.g. galvanically, chemically, by sputtering or by hot dipping. A high-temperature-resistant substrate is thus produced.

The metalization—both before and after it has been applied—may be patterned by, e.g. photolithographic, methods known per se in order to form in said metalization conductor tracks which serve for making contact with and/or interconnecting the devices mounted on the heat-dissipating insulation layer. The devices can be soldered, welded, adhesively bonded or clamped onto the conductor tracks for this purpose.

An embodiment provides for an initialization layer to be applied to the oxide layer, the metalization being produced on said initialization layer by growth (e.g. by electrodeposition).

One preferred variant for producing the metalization on the oxide layer provides for the metalization to be laminated onto the oxide layer. In this case, it is possible to provide a thin plastic layer which is preferably admixed with “fillers” for improving the thermal conductivity. The plastic layer serving as an adhesion promoter may be very thin, so that it does not impair the thermal conductivity of the substrate; it additionally also has the positive side effect of additional electrical insulation.

It is also possible for the metalization or conductor tracks to be adhesively bonded on, screwed on or else soldered on or welded on as individual elements if a corresponding metalization is present.

It is possible to produce a multilayer substrate by multilayered application of metalizations.

An embodiment that is cost-effective and advantageous in terms of production engineering provides for the basic body preferably to comprise aluminum or aluminum alloy (e.g. silicon-aluminum, aluminum-silicon) or titanium, tantalum or magnesium and the oxide layer to be a substrate metal oxide layer. However, it is also possible to apply to a basic body made of a different material—e.g. made of copper—an oxidizable layer—e.g. an aluminum layer—which at least partly (layer by layer) serves as insulation layer after its (anodic) oxidation (e.g. to form Al₂O₃).

A further embodiment provides for the basic body to be a cooling element. The cooling element may be formed e.g. as an air cooler or as a liquid cooler. The basic body, in a dual function, thus performs both a mechanically stabilizing function and a heat-dissipating function, there advantageously being no additional thermal interface between heat-dissipating insulation layer and cooling element.

As already discussed, oxide layer and metallic starting material have different thermal expansion properties. The latter may lead to mechanical stresses which, in the worst case, cause cracking in the oxide layer. Against this background, one embodiment provides for the oxide layer or the oxide layer islands to have a rounded edge profile.

The mechanical stresses may preferably also be reduced (further) by virtue of the oxide layer or the oxide layer islands having a layer thickness that decreases toward the edges thereof.

As an alternative or in addition, the oxide layer or the oxide layer islands, for mechanically decoupling from the basic body, may preferably be surrounded by a peripheral trench. The trench may advantageously have rounded corner regions.

In a preferred manner in terms of production engineering, the trench may be produced by embossing and subsequent heat treatment of the basic body or the layer made of metallic material, by casting—e.g. by aluminum die-casting—, by erosion, milling or by deep-drawing of the basic body material, in which case the planes of trench and/or island may lie at the same level as the surface of the basic body or alternatively above or below that.

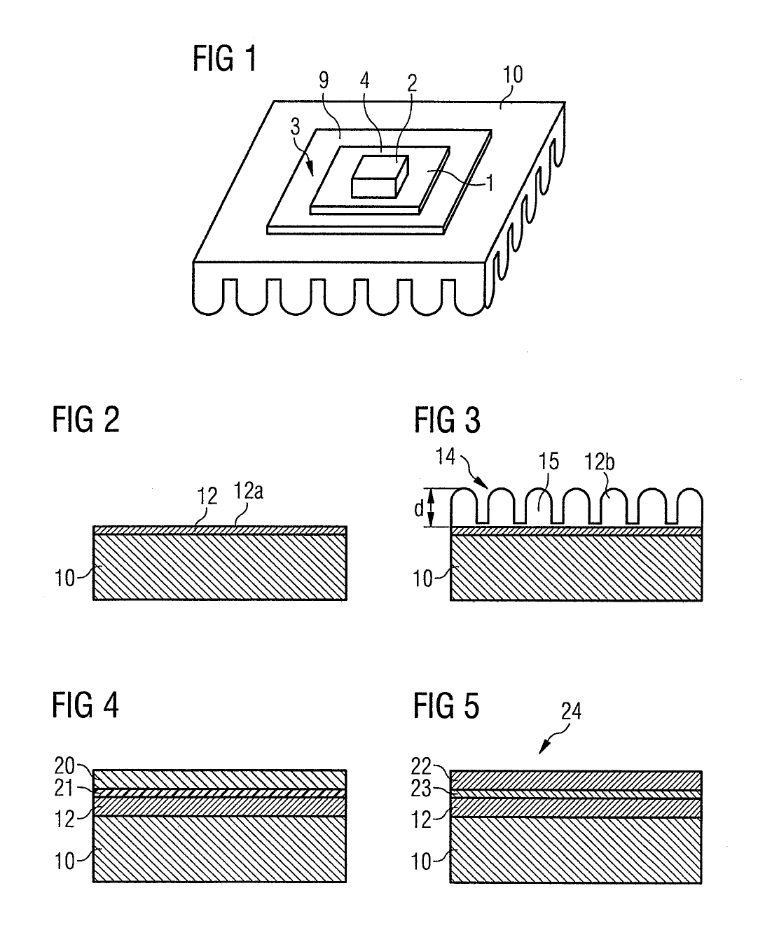

FIG. 1 schematically shows a detail from a power semiconductor module comprising a heat-dissipating insulation layer formed as substrate 1, on which a power semiconductor device (e.g. a power diode) 2 is arranged. A metalization 4 is applied to the top side 3 of the substrate 1, in which metalization conductor tracks (not illustrated) may be formed by corresponding patterning. The underside of the device 2 is electrically and mechanically connected to the metalization 4. Electrical power loss that unavoidably arises in the form of heat during the operation of the device 2 is dissipated to the surroundings by external cooling devices because otherwise excessively high temperatures may occur in the device or the rest of the components and lead to mechanical and/or electrical damage. For this purpose, the substrate comprises a basic body 10 on the underside, said basic body simultaneously being configured as a cooling element.

The cooling element, which comprises metal for the purpose of good thermal conduction, is electrically insulated from the device or the metalization for technical circuitry reasons. An electrical insulator 9 is provided for this purpose.

FIGS. 2 and 3 show a substrate according to an embodiment, with a basic body 10 made of metal—to be precise here made of aluminum. An oxide layer 12 made of aluminum oxide Al₂O₃ is grown on said basic body; this layer 12a (FIG. 2), which has arisen only as a result of natural growth processes, is usually relatively thin and can therefore insulate only relatively low electrical voltages.

As shown in FIG. 3, by means of suitable methods known per se, it is possible to grow a significantly thicker aluminum oxide layer 12b as high-voltage-resistant insulation layer 14 having a layer thickness d. Suitable methods for this purpose include e.g. anodic oxidation methods (e.g. anodizing method, phase electrolytic oxidation, hard anodization or micro arc oxidation).

The layer thickness d is dimensioned according to the voltages that are operationally to be expected and are to be reliably insulated and can be adapted or formed as required by correspondingly setting the process parameters (e.g. oxidation current, temperature, etc.). It is thus possible to realize an oxide layer thickness which overall is only very small but is sufficiently voltage-resistant and which impairs the thermal conductivity only to an insignificant extent.

The oxide layer 12b may contain “fillers” 15, which further improve the thermal and/or electrical conductivity of the insulation layer 14. By virtue of the solid basic body 10, the substrate can be subjected to high mechanical loading and is mechanically durable. In this case, too, the basic body may preferably be formed as a cooling element.

The substrate is thus optimized with regard to a minimum insulation layer thickness and at the same time ensures a very good thermal coupling of the electronic devices applied on the metalization to a cooling element in conjunction with very high mechanical stability.

FIGS. 4 and 5 show details from a substrate according to an embodiment in order to illustrate variants appertaining to the application of the metalizations.

FIG. 4 shows a metal film 20 laminated on in a manner known per se from printed circuit board (PCB) technology by means of an underlying thin plastic layer 21, e.g. made of epoxy. The plastic layer is applied to the oxide layer 12 of the basic body 10 and serves as an adhesion promoter with an optional additional insulation effect. Since it is made very thin, it practically does not impair the thermal conductivity of the substrate according to embodiment. In this method, the metalization (metal film) 20 may be patterned before or after being applied by lamination.

FIG. 5 shows a variant in which the metalization 22 is grown onto the oxide layer 12 by way of an initialization layer 23. The initialization layer may be formed e.g. from polymorphic glass, on which a copper layer 24 is then grown e.g. as metalization. This substrate is high-temperature-resistant since it is free of substances having a low melting point or decomposing substances (e.g. plastics).

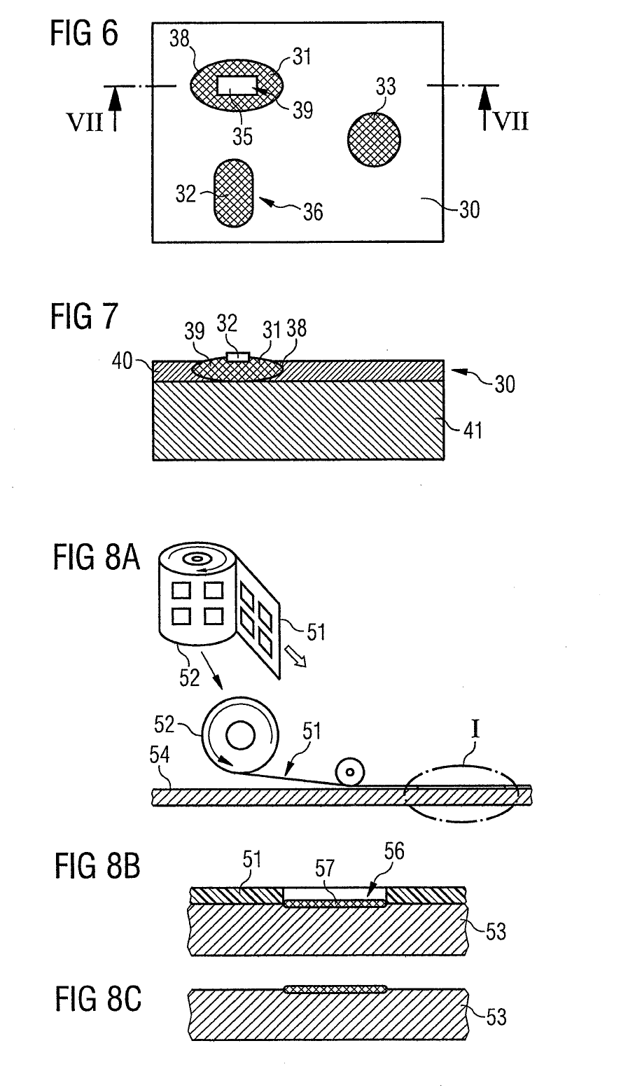

FIG. 6 shows a basic body 30 with a plurality of islands 31, 32, 33 made of oxide applied thereon. Devices or assemblies can be mounted on said islands in an electrically insulated manner, FIG. 6 showing only one device 35 by way of example. The islands or oxide layers in each case have rounded edge profiles; for this purpose, they are made e.g. circular or oval or have—as can be discerned in the case of the island 32—rounded corner regions 36. This configuration helps to keep down the mechanical stresses that occur owing to the different thermal properties (coefficients of expansion) of the islands, on the one hand, and the non-oxidized basic body material, on the other hand. This primarily prevents cracking in the edge region.

In addition, as shown in FIG. 7 with the illustration of a cross section along the line VII-VII in FIG. 6, the islands 31 may have an oxide layer thickness which rises from the island edges 38 toward the island center 39, in which case the island may be wider in the vertical central region than in the region of the top side. As can furthermore be discerned in FIG. 7, the oxide islands are formed in a metal layer 40 applied to the basic body 41 of the substrate 30.

FIG. 8 schematically shows a patterning process by which the desired geometries of the oxide islands can be produced. In process step A, a film 51 provided with openings in accordance with the desired island positions is applied to a carrier (substrate) 53 from a supply roll 52. The top side 54 of the substrate is thereby masked; such a masking could also be produced by the application of resist or a photolithographic process.

Afterward (as shown in step B on the basis of the enlarged detail I), the substrate is dipped into an electrolyte bath. In the process, in the region of the cutouts 56 of the film 51, the desired oxide islands 57 are produced on the metallic material of the substrate 53 (step B). The masking, i.e. the film 51, is then removed or stripped away again (step C) to leave the substrate top side provided with oxide islands.

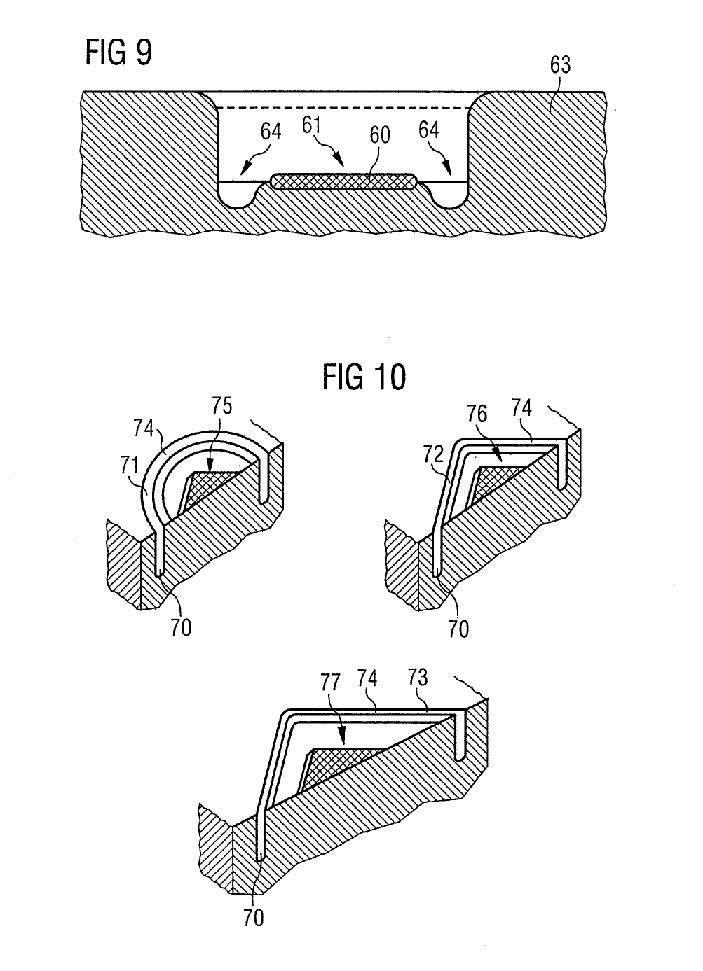

FIGS. 9 and 10 show possible shaping configurations of the substrate for further minimization of the mechanical loadings by reduction of the mechanical coupling between oxide layer and substrate material.

In this respect, FIG. 9 shows a greatly enlarged illustration of an oxide island 60 formed in a depression 61 of a basic body 63. A peripheral rounded depression or a trench 64 is provided around the island region.

FIG. 10 shows three variants of a trench configuration, which are all distinguished by avoiding pointed transitions or sharp edges or corners. Both the respective bottom region 70 of the trenches 71, 72, 73 and the changes in direction that occur in the trench profile are effected in rounded and gentle fashion. The top-side transitions 74 between trench and basic body top side (also see FIG. 9), are also formed in fluid and rounded fashion. This leads to an even further reduced susceptibility to cracking. As described above, respective oxide islands 75, 76, 77 are surrounded by the trenches 71, 72, 73. The structures illustrated can be produced in the basic body e.g. by embossing and subsequent heat treatment for annealing the mechanical stresses introduced by the embossing. It is also conceivable to produce the trench structures by milling or by casting of the basic body with simultaneous formation of the trenches.

The invention thus provides a substrate which, by known means and tried and tested technologies, has only the oxide layer thickness which is required according to the electrical dimensions and which hardly impairs the thermal conductivity and the very thin formation of which nevertheless does not cause mechanical instabilities.

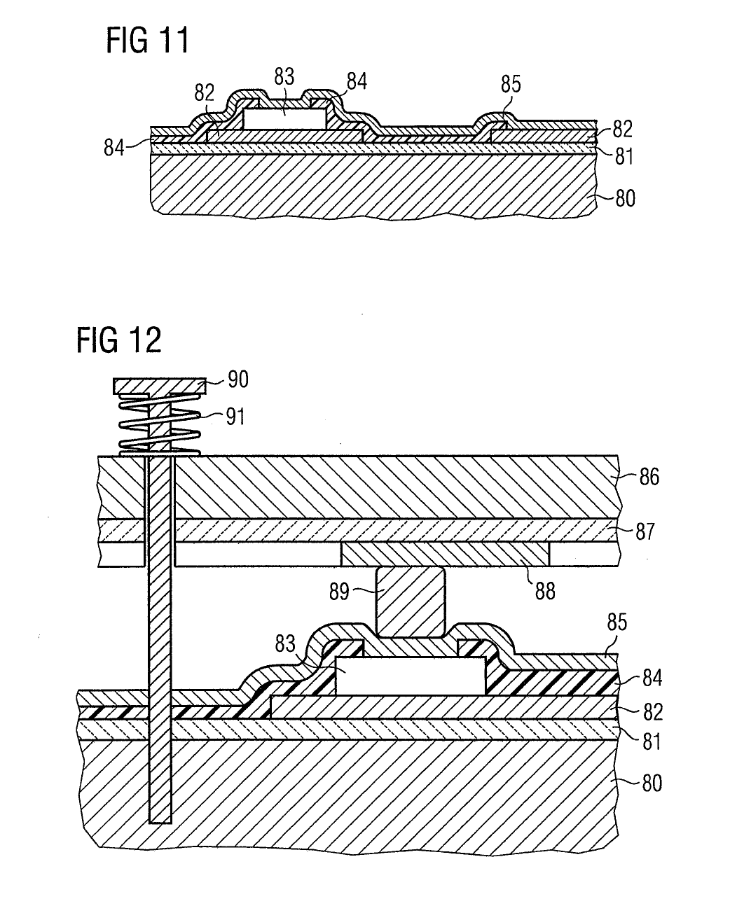

In the case of the power semiconductor module according to an embodiment in accordance with FIG. 11, an electrical insulation layer in the form of an oxide layer 81 is applied on a carrier material—a heat sink 80 in the present case. A patterned metalization in the form of conductor tracks 82 is in turn applied on the oxide layer 81. The oxide layer 81 and the conductor tracks 82 are produced in the manner described in FIGS. 1 to 10. An electrical component—a MOS transistor 83 in the present case—is mechanically fixed at a specific location of the conductor track 82 by soldering, for example, and electrically connected to the conductor tracks 82.

An insulating film 84 is laminated on over this arrangement comprising heat sink 80, oxide layer 81, conductor tracks 82 and also MOS transistor 83. The film 84 has cutouts at specific locations of the conductor track 82 and of the MOS transistor 83. In this case, the film may comprise for example a specific plastic material such as, for instance, polyamide, polyethylene, polyphenol, polyether ketone and/or epoxide. In this case, the cutouts can be introduced into the film as early as prior to the lamination, or else preferably after the lamination by opening the laminated-on film at the corresponding locations. A metalization 85 is then applied to the film 84 and also, in the cutouts, to the conductor track 82 and the MOS transistor 83. In this case, the film 84 simultaneously serves as masking for the metalization 85 and may alternatively also be embodied as a hard material mask or resist mask, in particular photoresist mask. A metal spraying technology is preferably used for producing the metalization 85. Afterward (not illustrated in the drawing for the sake of simplicity) an insulating film, a photoresist or the like may in turn be applied and serve as a mask and also electrical insulation for further metalizations. The use of metal spraying technologies is distinctly advantageous compared with customary galvanic metalizations, for example, with regard to the outlay in respect of time, materials and apparatus. What is more, thicker layers (greater than 1 mm) can be produced thereby. Application of a metalization in conjunction with insulating films being laminated on achieves, in a simple manner, an electrical contact-connection at the top side of the components and conductor tracks which is distinguished by a small structural height, a low susceptibility to faults and by extended possibilities for use.

The result is a low-resistance and low-inductance connecting structure of the electrical components both at the top side and at the underside. The contact areas can be larger by a multiple in relation to the typical bonding wire connections. Moreover, the structural volume is considerably reduced since bonding wire geometries no longer stand out from the carrier material.

FIG. 12 illustrates a development of the arrangement according to FIG. 11. Proceeding from the arrangement shown in FIG. 11 comprising a heat sink 80, an insulating oxide layer 81, a patterned metalization situated thereon in the form of conductor tracks 82, a component 83 fixed thereto, a film 84 laminated on across the latter, and also the metalization 85 situated thereon, a system level is constructed which is similar in the opposite order to that system level which are formed by the heat sink 80, the insulating oxide layer 81 and the conductor tracks 82. Accordingly, an arbitrary insulating layer 87 is applied at the underside of a further heat-dissipating carrier material, a heat spreader 86 in the present case, a patterned metalization 88 being situated at the free surface of said insulating layer. In the simplest case, however, a whole-area metalization may be provided instead of a patterned metalization 88. In this case, the metalization 88 and the metalization 85 are both electrically and thermally connected to one another by means of a coupling piece 89. For this purpose, the coupling piece 89 is embodied in solid fashion and from metal, so that it has good electrical and thermal conduction properties. However, the coupling piece may also be produced by partial solid application e.g. by electroplating or metal spraying.

The coupling piece 89 is coupled to the metalization 85 and the metalization 88 by pressing on (soldering, welding, adhesive bonding etc. also possible), the pressing-on pressure being obtained by means of a pressing-on apparatus—only parts of which are shown in FIG. 12—comprising a screw apparatus 90, which passes through the heat spreader 86, the associated oxide layer 87, the patterned metalization 88 and also through the metalizations 85, the insulating film 84, if appropriate the metalization 82 and also the oxide layer 81 and is screwed into a thread in the heat sink 80, and a spring element 91. The spring element 91 is arranged between the head of the screw apparatus 90 and the heat spreader 86 and provides the necessary force for the pressing-on process.

What is achieved, then, by the use of the heat spreader 86 is that the electrical component (the MOS transistor 83 in the exemplary embodiment) is cooled and electrically contact-connected on both sides. This means that the thermal resistance of the component is considerably reduced and the performance of the power semiconductor module is significantly increased. What is more, it is also possible to realize more extensive electrical interconnections in the heat spreader level. In this case, the further electrical insulation layer (oxide layer 87) situated at this level enables the electrical insulation between the conductor tracks of the metalization 88 and the heat spreader body. In order to mechanically couple the two levels, the arrangement is held—as shown—by means of a spring, heat spreader 86 and heat sink 80 being positioned and fixed.

### LIST OF REFERENCE SYMBOLS

1 Substrate
2 Power semiconductor device
3 Top side
4 Metalization
9 Insulator
10 Basic body
12 Oxide layer
12a Layer
12b Layer
14 Insulation layer
15 Filler
20 Metal film
21 Plastic layer
22 Metalization
23 Initialization layer
24 Copper layer
30 Basic body
31, 32, 33 Oxide island
35 Device
36 Corner regions
38 Island edges
39 Island center
40 Metal layer
41 Basic body
51 Film
52 Supply roll
53 Carrier (substrate)
54 Substrate top side
56 Cutouts
57 Oxide islands
60 Oxide island
61 Depression
63 Basic body
64 Trench
70 Bottom region
71,72,73 Trenches
74 Transitions
75,76,77 Oxide islands
80 Heat sink
81,87 Oxide layer
82 Conductor track
83 MOS transistor
84 Insulating film
85,88 Metalization
86 Heat spreader
89 Coupling piece
90 Screw apparatus
91 Spring element
A, B, C Process steps
d Layer thickness

1. A power semiconductor arrangement comprising
a heat-dissipating basic body having at least one exterior side formed in planar fashion, the basic body comprising metallic material or being provided with a layer made of metallic material and, at its exterior side, an electrically insulating oxide layer is at least partly formed on the metallic material,
at least one power semiconductor device arranged on said one exterior side of the basic body in such a way that it is electrically insulated from the basic body by the oxide layer,
an electrically insulating film that is at least partly laminated onto said one exterior side across said one power semiconductor device, the film having cutouts for making contact with said one power semiconductor device in the region of said one power semiconductor device, and
an upper metalization applied to the film and, in the cutouts thereof, to the power semiconductor device in large-area fashion or in patterned fashion.

2. The power semiconductor arrangement according to claim 1, wherein the upper metalization is applied to the film and, in the cutouts thereof, to the power semiconductor device by means of lamination.

3. The power semiconductor according to claim 1, wherein the upper metalization is applied to the film and, in the cutouts thereof, to the power semiconductor device by means of metal spraying technology.

4. The power semiconductor arrangement according to claim 1, wherein the oxide layer is formed by oxidation of the metallic material.

5. The power semiconductor arrangement according to claim 4, wherein the thickness of the oxide layer is dimensioned according to the voltage to be insulated from the power semiconductor device.

6. The power semiconductor arrangement according to claim 1, wherein further material for further increasing the electrical insulation properties and/or the mechanical strength and/or the thermal conductivity is applied to and/or introduced into the oxide layer.

7. The power semiconductor arrangement according to claim 1, wherein a lower metalization for mounting and making contact with the device is provided on the oxide layer.

8. The power semiconductor arrangement according to claim 7, wherein an initialization layer is applied to the oxide layer, the lower metalization being produced on said initialization layer by growth.

9. The power semiconductor arrangement according to claim 7, wherein the lower metalization is laminated onto the oxide layer.

10. The power semiconductor arrangement according to claim 1, wherein the basic body comprises aluminum or aluminum alloy and the oxide layer is an aluminum oxide layer.

11. The power semiconductor arrangement according to claim 1, wherein the basic body is a cooling element.

12. The power semiconductor arrangement according to claim 1, wherein the oxide layer has a rounded edge profile.

13. The power semiconductor arrangement according to claim 1, wherein the oxide layer has a layer thickness that decreases toward its edges.

14. The power semiconductor arrangement according to claim 1, wherein the oxide layer is mechanically decoupled from the basic body.

15. The power semiconductor arrangement according to claim 14, wherein the oxide layer, for mechanical decoupling from the basic body, are surrounded by a peripheral trench.

16. The power semiconductor arrangement according to claim 15, wherein the trench has rounded corner regions.

17. The power semiconductor arrangement according to claim 15, wherein the trench is produced by embossing and subsequent heat treatment of the basic body or the layer made of metallic material.

18. The power semiconductor arrangement according to claim 1, wherein a further heat-dissipating basic body is provided, which is in electrical and/or thermal contact with the upper metalization.

19. The power semiconductor arrangement according to claim 18, wherein the electrical and/or thermal contact is produced by means of at least one contact element.

20. The power semiconductor arrangement according to claim 18, wherein a further heat-dissipating basic body has at least one exterior side formed in planar fashion, comprises metallic material or is provided with a layer made of metallic material and, at its exterior side, an electrically insulating oxide layer is at least partly formed on the metallic material.

21. The power semiconductor arrangement according to claim 1, wherein the film comprises polyimide, polyethylene, polyphenol, polyether ether ketone and/or epoxy resin.

22. The power semiconductor arrangement according to claim 1, wherein a plurality of films and metalizations are arranged one above another.
